(19) United States
(12) Patent Application Publication
(10) Pub. No.: US 2015/0102307 A1
(43) Pub. Date: Apr. 16, 2015

(54) ELECTROLUMINESCENT ELEMENT, METHOD FOR MANUFACTURING ELECTROLUMINESCENT ELEMENT, DISPLAY DEVICE, AND ILLUMINATION DEVICE

(71) Applicants: Masaru Tajima, Tokyo (JP); Yusuke Yamazaki, Tokyo (JP); Yoshiaki Takahashi, Tokyo (JP)

(72) Inventors: Masaru Tajima, Tokyo (JP); Yusuke Yamazaki, Tokyo (JP); Yoshiaki Takahashi, Tokyo (JP)

(73) Assignee: SHOWA DENKO K.K., Minato-ku, Tokyo (JP)

(21) Appl. No.: 14/381,474

(22) PCT Filed: Feb. 29, 2012
(86) PCT No.: PCT/JP2012/055131

§ 371 Date: Aug. 27, 2014

(51) Int. Cl. H01L 51/52; H01L 51/56

(52) U.S. Cl. CPC H01L 51/5215; H01L 51/5212; H01L 51/56
USPC 257/40; 438/46

(57) ABSTRACT

An electroluminescent element including a substrate and a layered part having a first electroconductive layer, a dielectric layer, a second electroconductive layer, a light-emitting layer and a third electroconductive layer. Plural contact holes that pass through at least the dielectric layer are disposed in the dielectric layer, the first and second electroconductive layers are electrically connected inside the contact holes, the refractive indices of the second electroconductive layer and light-emitting layer are 1.5 to 2.0 inclusive, the absolute value of the difference between the refractive indices, respectively, and the refractive index of the dielectric layer is 0.1 or more. Further, (i) the light-emitting surface side has at continuous light-emitting region, and (ii) the number of contact holes is 10² or more per a single light-emitting region and the ratio of the total surface area occupied by the plural contact holes is 0.1 or less.

### TECHNICAL FIELD

The present invention relates to an electroluminescent element, a method for manufacturing the electroluminescent element, a display device, and an illumination device.

### BACKGROUND ART

In recent years, devices utilizing the electroluminescence phenomenon have increased in importance. As a device like this, an electroluminescent element in which light-emitting materials are formed to be a light-emitting layer, and a pair of electrodes including an anode and a cathode is attached to the light-emitting layer, and light is emitted by applying a voltage thereto, receives attention. In such an electroluminescent element, holes and electrons are injected from the anode and the cathode, respectively, by applying a voltage between the anode and the cathode, and an energy generated by coupling the injected electrons and holes in the light-emitting layer is used to perform light emission.

In the case where this electroluminescent element is used as a display device, since the light-emitting material is capable of self-emitting, the device has characteristics that a response speed as the display device is fast and a view angle is wide. Further, due to its structural feature of the electroluminescent element, there is an advantage that the thickness of the display device may be reduced with ease. Moreover, in the case of an organic electroluminescent element using, for example, an organic substance as the light-emitting material, characteristics are obtained such that light with high color purity is readily obtained depending upon selection of the organic substance, and thereby a wide color gamut is available.

Further, since the electroluminescent element is capable of emitting light of its own color, and is an area light source, a proposal of usage of the electroluminescent element to be incorporated into an illumination device is also made.

Conventionally, as an electroluminescent element, there is known an organic layer including a light-emitting layer that is formed to be interposed between a cathode and an anode, in which the light-emitting layer in a region where the anode and the cathode overlap emits light by application of voltage between these electrodes.

Moreover, in Patent Document 1, an organic light-emitting element is disclosed, in which one of electrodes is electrically connected to a semiconductor layer, and thereby light is emitted in a light-emitting layer interposed between the semiconductor layer and the other one of electrodes. In this organic light-emitting element, since emitted light is able to be extracted from the semiconductor layer to the outside, the electrodes can be formed by an opaque material, and therefore, a metal having high conductivity and chemical stability is able to be used as a material of the electrodes.

### CITATION LIST

### Patent Literature

Patent Document 1: International Publication WO00/67531 Pamphlet

### DISCLOSURE OF INVENTION

### Technical Problem

Here, in the electroluminescent element, in which one of the electrodes is electrically connected to the semiconductor layer and the light-emitting layer interposed between the semiconductor layer and the other electrode emits light, the semiconductor layer is required to be formed in contact with the electrode after the electrodes are patterned. Accordingly, in a case where the electrodes are formed in a fine pattern, it becomes difficult to form a smooth semiconductor layer between the electrodes, and therefore, light emission within a light-emitting surface tends to be non-uniform. In addition, for smoothing the semiconductor layer, a smoothing process is required separately, to thereby complicate the production process and lead to increase in production costs.

In view of the above problem, an object of the present invention is to provide an electroluminescent element that is easily produced, in which the light-emitting surface in a light-emitting portion is smooth and brightness uniformity in the light-emitting surface is high.

### Solution to Problem

That is, the present invention includes following aspects [1] to [13].

[1] An electroluminescent element including: a substrate; and a lamination section including a first electroconductive layer, a dielectric layer, a second electroconductive layer, a light-emitting layer and a third electroconductive layer successively laminated on the substrate, wherein, in the dielectric layer, plural contact holes that pass through at least the dielectric layer are provided, the first electroconductive layer and the second electroconductive layer are electrically connected inside the plural contact holes, refractive indices of the second electroconductive layer and the light-emitting layer are not less than 1.5 and not more than 2.0, and an absolute value of a difference in each of the refractive indices with the refractive index of the dielectric layer is not less than 0.1, and when viewed from a light-emitting surface side from which light emitted in the light-emitting layer is taken out, (i) at least one continuous light-emitting region is provided, and (ii) a number of the contact holes is not less than 10² per the one light-emitting region and a ratio of a total area occupied by the plural contact holes to an area of the light-emitting region is not more than 0.1.
[2] The electroluminescent element according to aspect [1], wherein the ratio of the total area occupied by the plural contact holes to the area of the light-emitting region is 0.001 to 0.1.
[3] The electroluminescent element according to any one of aspects [1] and [2], wherein a cross-sectional shape of the contact hole in a case of being viewed in a plan view from the light-emitting surface side has a size able to be enclosed in a circle having a diameter in a range of 0.01 μm to 2 μm.
[4] The electroluminescent element according to any one of aspects [1] to [3], wherein the contact hole are formed to further pass through the first electroconductive layer.
[5] The electroluminescent element according to any one of aspects [1] to [4], wherein the first electroconductive layer, the dielectric layer and the second electroconductive layer are transparent to a wavelength of light emitted in the light-emitting layer.
[6] The electroluminescent element according to any one of aspects [1] to [5], wherein both of the refractive indices of the second electroconductive layer and the light-emitting layer are larger than the refractive index of the dielectric layer.
[7] The electroluminescent element according to any one of aspects [1] to [5], wherein both of the refractive indices of the second electroconductive layer and the light-emitting layer are smaller than the refractive index of the dielectric layer.
[8] The electroluminescent element according to any one of aspects [1] to [7], wherein the second electroconductive layer includes one of conductive metal oxide and conductive polymer.
[9] The electroluminescent element according to any one of aspects [1] to [8], wherein at least one layer, which is selected from a hole transporting layer, a hole blocking layer and an electron transporting layer, is further provided between the second electroconductive layer and the third electroconductive layer.
[10] A method for manufacturing an electroluminescent element including a continuous light-emitting region, the method including: a process of successively forming a first electroconductive layer and a dielectric layer on a substrate; a process of providing plural contact holes so that the plural contact holes pass through at least the dielectric layer, a number of the plural contact holes formed per the one light-emitting region is not less than 10², and a ratio of a total area occupied by the plural contact holes in the light-emitting region to an area of the light-emitting region is not more than 0.1; a process of filling the contact holes with the second electroconductive layer so that the second electroconductive layer is electrically connected to the first electroconductive layer inside the plurality of contact holes, and forming the second electroconductive layer on the dielectric layer so that a refractive index of the second electroconductive layer is not less than 1.5 and not more than 2.0, and an absolute value of a difference in the refractive indices between the second electroconductive layer and the dielectric layer is not less than 0.1; and a process of forming a light-emitting layer on the second electroconductive layer so that a refractive index of the light-emitting layer is not less than 1.5 and not more than 2.0, and an absolute value of a difference in the refractive indices between the light-emitting layer and the dielectric layer is not less than 0.1, and further forming a third electroconductive layer successively.
[11] The method for manufacturing an electroluminescent element according to aspect 10, wherein the second electroconductive layer is formed by a coating film-forming method.
[12] A display device including the electroluminescent element according to any one of aspects 1 to 9.
[13] An illumination device including the electroluminescent element according to any one of aspects 1 to 9.

### Advantageous Effects of Invention

According to the present invention, it is possible to provide an electroluminescent device with high light-emitting efficiency and high uniformity in light emission that is easily manufactured.

### BRIEF DESCRIPTION OF DRAWINGS

FIG. 1 is a partial cross-sectional view illustrating a specific example of a light-emitting region of an electroluminescent element to which the exemplary embodiment is applied;

FIGS. 2A and 2B are diagrams illustrating a size of a contact hole; and

FIGS. 3A to 3E are diagrams illustrating a specific example of a method for manufacturing the electroluminescent element.

### DESCRIPTION OF EMBODIMENTS

Hereinafter, exemplary embodiments according to the present invention will be described in detail. It should be noted that the present invention is not limited to the following exemplary embodiments, but may be practiced as various modifications within the scope of the gist of the invention. In other words, unless otherwise specified, dimensions, materials, shapes or relative arrangement of components described in the specific examples of the exemplary embodiments do not limit the scope of the present invention, but are merely descriptive specific examples. Further, each of the figures to be used indicates a specific example for illustration of each exemplary embodiment, and does not represent an actual size thereof. Moreover, in this specification, a phrase such as “above (on or over) a layer” is not only limited to a case of being formed on a layer in contact therewith, but also used to include a case of being formed above a layer with some separation, or a case including some layer being interposed between layers.

### <Electroluminescent Element>

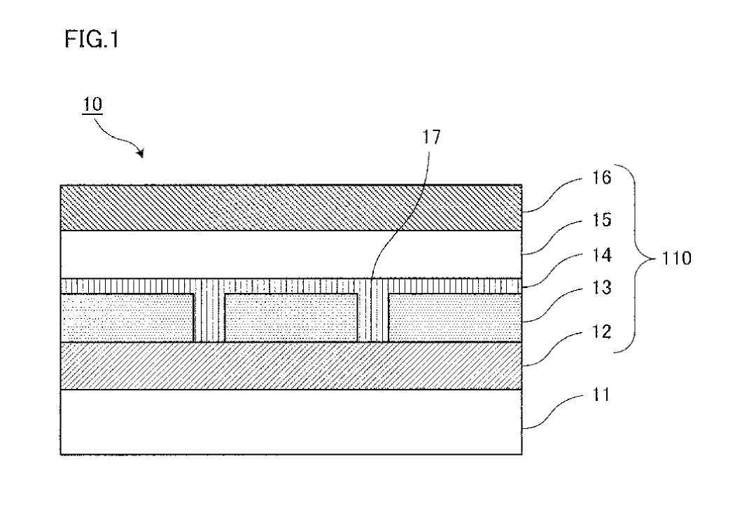

FIG. 1 is a partial cross-sectional view illustrating a specific example of a light-emitting region of an electroluminescent element 10 to which the exemplary embodiment is applied.

The electroluminescent element 10 shown in FIG. 1 includes a substrate 11 and a lamination section 110 formed on the substrate 11. In the lamination section 110, there are laminated in order from the substrate 11 side: a first electroconductive layer 12 for injecting holes; a dielectric layer 13 having insulation properties; a second electroconductive layer 14 that covers the top surface of the dielectric layer 13; a light-emitting layer 15 that emits light upon coupling the holes and electrons; and a third electroconductive layer 16 for injecting the electrons.

As shown in FIG. 1, in the dielectric layer 13 of the electroluminescent element 10, plural contact holes 17 that pass through the dielectric layer 13 are provided. Inside of each contact hole 17 is filled with a component constituting the second electroconductive layer 14.

In the exemplary embodiment, the contact hole 17 is filled only with the component of the second electroconductive layer 14. This connects the first electroconductive layer 12 and the second electroconductive layer 14 electrically inside the contact holes 17. Consequently, by applying the a voltage between the first electroconductive layer 12 and the third electroconductive layer 16, a voltage is applied between the second electroconductive layer 14 and the third electroconductive layer 16, to thereby cause the light-emitting layer 15 to emit light.

In this case, a surface of the light-emitting layer 15 on the substrate 11 side, a surface on the third electroconductive layer 16 side, which is opposite to the substrate 11 side, or both of these surfaces become the light-emitting surfaces from which light is taken out of the electroluminescent element 10. Moreover, in a case of being viewed from the surface on the substrate 11 side of the electroluminescent 10, or, in a case of being viewed from the surface on the third electroconductive layer 16 of the electroluminescent element 10, the light-emitting layer 15 emits light as a continuous light-emitting region.

It should be noted that, as another exemplary embodiment, the contact hole 17 may be filled with the components of the second electroconductive layer 14 and others by forming the second electroconductive layer 14 and further forming other components, such as the light-emitting layer 15, so as to contact the contact hole 17.

### (Substrate 11)

The substrate 11 serves as a support body that forms the first electroconductive layer 12, the dielectric layer 13, the second electroconductive layer 14, the light-emitting layer 15 and the third electroconductive layer 16. Usually, a material that satisfies mechanical strength required for a support body of the electroluminescent element 10 is used for the substrate 11.

The material for the substrate 11, in the case where the light is to be taken out from the substrate 11 side of the electroluminescent element 10 (that is, in the case where the surface of the substrate 11 side is the light-emitting surface from which the light is taken out), is preferably a material that is transparent to the wavelength of light emitted in the light-emitting layer 15. Specifically, in a case where the light emitted in the light-emitting layer 15 is visible light, for example: glasses such as soda glass and non-alkali glass; transparent plastics such as acrylic resins, methacrylic resins, polycarbonate resins, polyester resins and nylon resins; silicon and the like are provided.

It should be noted that, in the exemplary embodiment, “transparent to the wavelength of light emitted in the light-emitting layer 15” means that it is enough to transmit light with a constant wavelength range emitted from the light-emitting layer 15, and it is unnecessary to have optical transparency over the entire visible light region. However, in the exemplary embodiment, it is preferable that the substrate 11 transmits light, as visible light, having a wavelength of 450 nm to 700 nm. Moreover, as transmittance, it is preferable to have not less than 50%, and more preferable to have not less than 70%, in a wavelength with a maximum light-emitting intensity.

In a case where it is unnecessary to take out light from a surface on the substrate 11 side of the electroluminescent element 10, the material of the substrate 11 is not limited to the ones which are transparent, and opaque materials can be used. Specifically, in addition to the above-described materials, a material composed of: a simple substance such as copper, silver, gold, platinum, tungsten, titanium, tantalum or niobium; alloys thereof; stainless steel or the like; can be used.

Though being adequately selected depending on the required mechanical strength also, the thickness of the substrate 11 is preferably 0.1 mm to 10 mm, and more preferably 0.25 mm to 2 mm.

### (First Electroconductive Layer 12)

Upon application of a voltage between the first electroconductive layer 12 and the third electroconductive layer 16, the first electroconductive layer 12 injects holes to the light-emitting layer 15 via the second electroconductive layer 14. In other words, in the exemplary embodiment, the first electroconductive layer 12 is an anode layer. A material used for the first electroconductive layer 12 is not particularly limited as long as the material has electric conductivity. However, usually, a sheet resistance of the material in a temperature range of −5° C. to 80° C. is preferably not more than 1000Ω, and more preferably, not more than 100 Ω.

As the material satisfying such requirements, for example, conductive metal oxides, metals, alloys or the like can be provided. Here, as the conductive metal oxides, for example, indium tin oxide (ITO), indium zinc oxide (IZO), tin oxide, zinc oxide, and so on are provided. As the metals, copper, silver, gold, platinum, tungsten, titanium, tantalum, niobium, and the like are provided. Moreover, alloys including these metals can also be used. Of these materials, as the transparent materials used for forming a transparent electrode, ITO, IZO and tin oxide are preferable. In addition, a transparent conductive film composed of organic substances such as polyaniline or derivatives thereof, polythiophene or derivatives thereof and the like may be used.

The thickness of the first electroconductive layer 12 is, in the case where the surface on the substrate 11 side of the electroluminescent element 10 becomes the light-emitting surface, from which light is taken out, preferably 2 nm to 300 nm for obtaining high optical transparency. Moreover, in the case where there is no need to take out light from the substrate 11 side of the electroluminescent element 10, for example, the first electroconductive layer 12 can be formed with a thickness of 2 nm to 2 mm.

It should be noted that, for the substrate 11, a material same as that of the first electroconductive layer 12 can also be used. In this case, the substrate 11 may serve as the first electroconductive layer 12.

### (Dielectric Layer 13)

The dielectric layer 13 is laminated on the first electroconductive layer 12, and a material transparent to the light emitted in the light-emitting layer is used.

As specific materials constituting the dielectric layer 13, for example, metal nitrides such as silicon nitride, boron nitride and aluminum nitride, and metal oxides such as silicon oxide and aluminum oxide are provided. Further, polymer compounds such as polyimide, polyvinylidene fluoride and parylene can also be used.

It is preferable that the thickness of the dielectric layer 13 does not exceed 1 μm for suppressing increase of electrical resistance between the first electroconductive layer 12 and the second electroconductive layer 14. However, if the thickness of the dielectric layer 13 is too thin, there is a possibility that an effect of changing a traveling direction of light, which will be described later, is not sufficiently obtained. Accordingly, the dielectric layer 13 may be formed with a thickness of preferably 10 nm to 500 nm, and more preferably, 50 nm to 200 nm.

The shape of the contact hole 17 formed to pass through the dielectric layer 13 is not particularly limited, and the shape may be, for example, a cylindrical shape, a quadrangular prism shape, or the like.

Moreover, in the exemplary embodiment, the contact hole 17 is formed to pass through the dielectric layer 13 only; however, not limited to the exemplary embodiment. For example, the contact hole 17 may be formed to further pass through the first electroconductive layer 12.

The dielectric layer 13 is capable of increasing light to be taken out of the electroluminescent element 10 by refracting the light incident from the light-emitting layer 15 via the second electroconductive layer 14 and changing the traveling direction of light. To do this, each of the refractive indices of the second electroconductive layer 14 and the light-emitting layer 15 may be not less than 1.5 and not more than 2.0, and an absolute value of the difference (Δn) between each of the refractive indices and the refractive index of the dielectric layer 13 may be not less than 0.1. The larger the absolute value of the difference (Δn) in refractive indices, the greater the traveling direction of light changes. In other words, since it is possible to take more light out of the electroluminescent element 10, the absolute value of the difference (Δn) in refractive indices is preferably not less than 0.2.

Moreover, it is preferable that both of the refractive indices of the second electroconductive layer 14 and the light-emitting layer 15 are larger than the refractive index of the dielectric layer 13 or smaller than the refractive index of the dielectric layer 13. In other words, for example, as a material for forming the dielectric layer 13, it is preferable to use a low refractive index material having a refractive index of not more than 1.4 or a high refractive index material having a refractive index of not less than 2.1. Moreover, in a case where materials having refractive indices of not less than 1.7 are used as the materials for forming respective of the second electroconductive layer 14 and the light-emitting layer 15, it is preferable to use a material having a refractive index of not more than 1.6 as the material for forming the dielectric layer 13. It should be noted that, here, the refractive index indicates a refractive index for the d line of sodium (589.3 nm). However, if a material of any one of the dielectric layer 13, the second electroconductive layer 14 and the light-emitting layer 15 is a material that does not transmit light of this wavelength (589.3 nm), the refractive index indicates a refractive index for a wavelength with which intensity of light emitted in the light-emitting layer 15 becomes maximum.

### (Second Electroconductive Layer 14)

The second electroconductive layer 14 electrically contacts the first electroconductive layer 12 inside the contact hole 17 to inject the holes received from the first electroconductive layer 12 into the light-emitting layer 15. It is preferable that the second electroconductive layer 14 includes conductive metal oxides or conductive polymers. Specifically, the second electroconductive layer 14 is preferably a transparent conductive film, which has optical transparency, composed of conductive metal oxides, such as ITO, IZO and tin oxide, and organic substances, such as conductive polymer compounds. Moreover, in the exemplary embodiment, since the inside of the contact hole 17 is filled with a material to form the second electroconductive layer 14, it is preferable that the second electroconductive layer 14 is formed by coating for making it easy to form a film on an inner surface of the contact hole 17. Accordingly, from this point of view, it is especially preferable that the second electroconductive layer 14 is a transparent conductive film composed of organic substances, such as conductive polymer substances. It should be noted that the second electroconductive layer 14 and the first electroconductive layer 12 may be formed by use of the same material.

The thickness of the second electroconductive layer 14 is, in the case where the light is to be taken out from a surface on the substrate 11 side, preferably 2 nm to 300 nm for obtaining high optical transparency.

Moreover, in the exemplary embodiment, a layer for facilitating injection of the holes into the light-emitting layer 15 (for example, a hole injection layer, etc.) may be provided on a surface of the second electroconductive layer 14 that is brought into contact with the light-emitting layer 15. As such a layer, specifically, a layer of 1 nm to 200 nm composed of conductive polymers, such as phthalocyanine derivatives, polythiophene derivatives and the like, amorphous carbon, carbon fluoride, polyamine compound and the like, or a layer having an average thickness of not more than 10 nm composed of metal oxides, metal fluorides, organic insulating materials and the like, are provided.

### (Light-Emitting Layer 15)

The light-emitting layer 15 includes a light-emitting material that emits light by application of a voltage. As the light-emitting material contained in the light-emitting layer 15, any of organic materials and inorganic materials can be used. In the case of organic materials (luminescent organic materials), any of low-molecular compounds (luminescent low-molecular compounds) and polymer compounds (luminescent polymer compounds) can be used. As luminescent organic materials, phosphorescent organic compounds and metal complexes are preferred.

In the exemplary embodiment, from the viewpoint of improving the light-emitting efficiency of the light-emitting layer 15, it is particularly preferable to use cyclometalated complexes. As the cyclometalated complexes, for example, complexes of iridium, palladium, platinum and the like including ligands such as 2-phenylpyridine derivatives, 7,8-benzoquinoline derivatives, 2-(2-thienyl)pyridine derivatives, 2-(1-naphthyl) pyridine derivatives, 2-phenylquinoline derivatives are provided. Of these, iridium complexes are especially preferred. The cyclometalated complexes may include ligands other than the ligands required to form the cyclometalated complexes.

As the luminescent polymer compounds, for example, there are provided: polymer compounds of a n-conjugated system, such as poly-p-phenylenevinylene (PPV) derivatives, polyfluorene derivatives and polythiophene derivatives; polymers introducing low-molecular pigments and tetraphenyldiamine or triphenylamine to a main chain or a side chain; and the like. The luminescent polymer compounds and the luminescent low-molecular compounds can be used in combination.

The light-emitting layer 15 includes the light-emitting material and a host material, and the light-emitting material is dispersed in the host material in some cases. It is preferable that the host material has charge transporting properties, and it is also preferable that the host material is a hole-transporting compound or an electron-transporting compound. It should be noted that, as the hole-transporting compound or the electron-transporting compound, a known material can be used.

The thickness of the light-emitting layer 15 is appropriately selected in consideration of charge mobility, balance of injected charge or interference of emitting light and the like, and is not particularly limited. In the exemplary embodiment, the thickness of the light-emitting layer 15 is preferably 1 nm to 1 μm, more preferably 2 nm to 500 nm, and especially preferably 5 nm to 200 nm.

### (Third Electroconductive Layer 16)

A voltage is applied between the third electroconductive layer 16 and the first electroconductive layer 12 and the electrons are injected from the third electroconductive layer 16 to the light-emitting layer 15. In other words, in the exemplary embodiment, the third electroconductive layer 16 is a cathode layer.

A material used for the third electroconductive layer 16 is, similar to that of the first electroconductive layer 12, not particularly limited as long as the material has electric conductivity. In the exemplary embodiment, it is preferable that the material has a low work function and is chemically stable. Specifically, Al, alloys of Al and alkali metals, such as AlLi, alloys of Al and Mg, such as MgAl alloy, alloys of Al and alkaline earth metals, such as AlCa, and the like can be provided as specific examples.

However, in the case where the light is to be taken out from the third electroconductive layer 16 side of the electroluminescent element 10 (namely, in the case where the surface of the third electroconductive layer 16 side becomes the light-emitting surface, from which the light is to be taken out), it is preferable to use a material transparent to the emitted light as the material for the third electroconductive layer 16, similar to the first electroconductive layer 12.

The thickness of the third electroconductive layer 16 is preferably 0.01 μm to 1 μm, and more preferably 0.05 μm to 0.5 μm.

In the exemplary embodiment, with intent to lower the barrier for the electron injection from the third electroconductive layer 16 into the light-emitting layer 15, to thereby increase the electron injection efficiency, a cathode buffer layer (not shown) may be provided adjacent to the third electroconductive layer 16. The cathode buffer layer is required to have a lower work function than the third electroconductive layer 16, and metallic materials may be suitably used therefor. As such metallic materials, for example, alkali metals (Na, K, Rb and Cs), Mg and alkaline earth metals (Sr, Ba and Ca), rare earth metals (Pr, Sm, Eu and Yb), one selected from fluoride, chloride and oxide of these metals and mixture of two or more selected therefrom can be used. The thickness of the cathode buffer layer is preferably 0.05 nm to 50 nm, more preferably 0.1 nm to 20 nm, and still more preferably 0.5 nm to 10 nm.

Moreover, in the exemplary embodiment, a layer other than the light-emitting layer 15 may be formed between the second electroconductive layer 14 and the third electroconductive layer 16. As such a layer, for example, a hole transporting layer, a hole blocking layer, an electron transporting layer or the like can be provided. Each layer is formed, in response to the function thereof, by use of a known charge transporting material or the like. Moreover, the thickness of each layer is appropriately selected in consideration of charge mobility, balance of injected charge or interference of emitting light and the like, and is not particularly limited. In the exemplary embodiment, the thickness of each layer is preferably 1 nm to 500 nm, and more preferably, 5 nm to 200 nm.

### (Contact Hole 17)

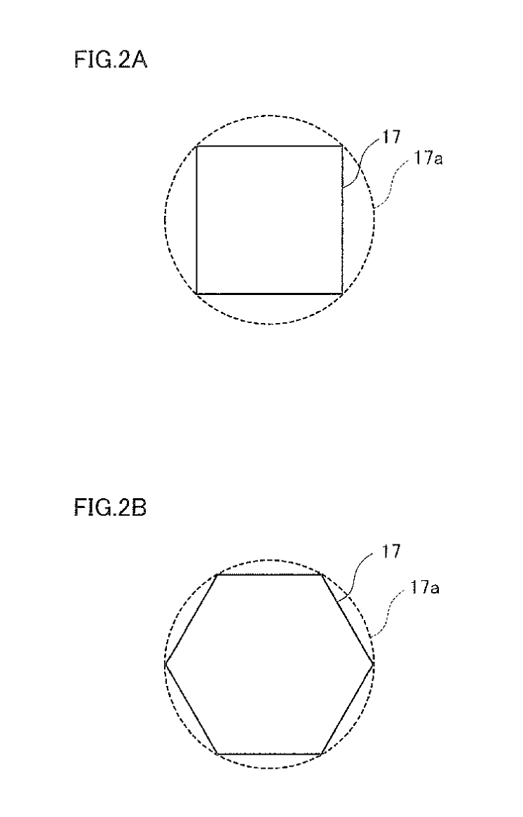

FIGS. 2A and 2B are diagrams illustrating a size of the contact hole 17. FIG. 2A shows, for example, a case in which the contact hole 17 has a cross-sectional shape of a square as the light-emitting surface of the light-emitting layer 15 is viewed in a plan view from a perpendicular direction with respect to the substrate 11, and FIG. 2B shows a case in which the cross-sectional shape thereof is a hexagon. In the exemplary embodiment, as shown in FIGS. 2A and 2B, the size of the contact hole 17 is represented by use of a diameter of a minimum circle 17a enclosing the above-described shape of the contact hole 17 (the minimum enclosing circle) in the case of viewing the contact hole 17 in a plan view.

In the exemplary embodiment, from the viewpoint of increasing the area of the light-emitting layer 15 to be formed on the dielectric layer 13 and brightness of the electroluminescent element 10, the size of the contact hole 17 is preferably as small as possible as long as electrical connection between the first electroconductive layer 12 and the second electroconductive layer 14 is fully available.

From the viewpoint like this, the diameter of the minimum enclosing circle 17a is preferably 0.01 μm to 2 μm. For example, in the case where the contact hole 17 has a cylindrical shape, the diameter of the cylinder is preferably 0.01 μm to 2 μm.

In the exemplary embodiment, in the case where the dielectric layer 13 is viewed in the plan view from the light-emitting surface side of the light-emitting layer 15, the ratio of the total area occupied by the plural contact holes 17 to the area of the light-emitting region is preferably not more than 0.1, and especially preferably 0.001 to 0.1. In the case where the ratio of the total area occupied by the contact holes 17 is within the above-described range, it becomes possible to obtain light emission with high brightness.

In the exemplary embodiment, the number of the contact holes 17 to be formed in one light-emitting region is at least not less than 10², and preferably not less than 10⁴. However, it is preferable that the number of contact holes 17 is such that, as described above, the ratio of the total area of the contact holes 17 in the light-emitting region surface is preferably in the range of not more than 0.1. It should be noted that, since FIG. 1 is a schematic view, it is not necessarily assumed to represent the ratio of each value.

In the exemplary embodiment, the plural contact holes 17 may be distributed uniformly or non-uniformly in the light-emitting region with a desired light-emitting mode. Moreover, the plural contact holes 17 in the light-emitting region may be arranged regularly or irregularly. However, in view of manufacturing, it is preferable that the plural contact holes 17 are arranged regularly. As a specific example of regular arrangement, for example, an arrangement of a cubic lattice or a hexagonal lattice can be provided. With such an arrangement, in the electroluminescent element 10 to which the exemplary embodiment is applied, a light-emitting portion is formed on the smooth dielectric layer 13, and it is possible to increase uniformity in light emission in the light-emitting region.

It should be noted that, in the above-described specific example, description was given of the case where the first electroconductive layer 12 was assumed to be the anode layer and the third electroconductive layer 16 was assumed to be the cathode layer; however, the specific example is not limited thereto, and the first electroconductive layer 12 may be the cathode layer and the third electroconductive layer 16 may be the anode layer.

### <Method for Manufacturing Electroluminescent Element>

Next, description will be given of a method for manufacturing an electroluminescent element, while the electroluminescent element 10 shown in FIG. 1 is taken as a specific example.

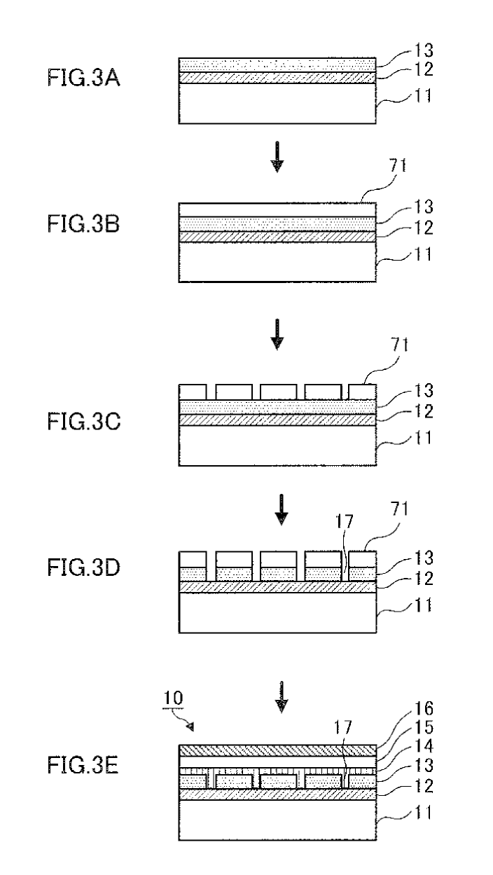

FIGS. 3A to 3E are diagrams for illustrating the method for manufacturing the electroluminescent element 10.

First, as shown in FIG. 3A, on the substrate 11, the first electroconductive layer 12 and the dielectric layer 13 are successively laminated. For forming these layers, a resistance heating deposition method, an electron beam deposition method, a sputtering method, an ion plating method, a CVD method or the like can be used. Alternatively, if a coating film-forming method (that is, a method for applying a target material solved in a solvent to the substrate and then drying the same) is applicable, the layers can be formed by a spin coating method, a dip coating method, an ink-jet printing method, a printing method, a spray-coating method and a dispenser-printing method or the like.

Next, the contact holes 17 are formed in the dielectric layer 13. For forming the contact holes 17, a method using photolithography may be provided, for example.

As shown in FIG. 3B, first, a photoresist solution is applied on the dielectric layer 13 and then an excess photoresist solution is removed by spin coating or the like to form a resist layer 71.

Subsequently, as shown in FIG. 3C, the photoresist layer 71 is covered with a mask, in which a predetermined pattern for forming the contact holes 17 is rendered, and is exposed with ultraviolet (UV), an electron beam (EB) or the like. Here, by performing same magnification exposure (for example, in a case of contact exposure or proximity exposure), a pattern of the contact holes 17 with the same magnification as the mask pattern can be formed. Moreover, if reduced exposure (for example, in a case of exposure using a stepper) is performed, a pattern of the contact holes 17 which is reduced with respect to the mask pattern can be formed. Next, unexposed portions of the photoresist layer 71 are removed by use of a developing solution, and thereby pattern portions of the photoresist layer 71 are removed and part of the dielectric layer 13 is exposed.

Next, as shown in FIG. 3D, the exposed portions of the dielectric layer 13 are removed by etching to form the contact holes 17. In this case, part of the first electroconductive layer 12 provided below the dielectric layer 13 may also be removed by etching. Either dry etching or wet etching can be used as the etching. Reactive ion etching (RIE) or inductive coupling plasma etching is provided as the dry etching. Moreover, as the wet etching, a method of immersion in diluted hydrochloric acid or diluted sulfuric acid is provided. It should be noted that, in performing etching, by controlling etching conditions (for example, a process time, gases to be used, pressure, and a substrate temperature), the layers to be penetrated by the contact holes 17 can be selected.

Moreover, the contact holes 17 can also be formed by a method of nanoimprinting. Specifically, after forming the photoresist layer 71, a mask in which convex patterns are rendered is pressed against the surface of the photoresist layer 71 with pressure. By applying heat and/or light to the photoresist layer 71 in this state, the photoresist layer 71 is cured. Next, the mask is removed, and thereby the pattern, which is a pattern of the contact holes 17 corresponding to the convex patterns on the mask, is formed on a surface of the photoresist layer 71. Subsequently, the contact holes 17 can be formed by performing the aforementioned etching.

Next, as shown in FIG. 3E, on the dielectric layer 13, on which the contact holes 17 have been formed, the second electroconductive layer 14, the light-emitting layer 15 and the third electroconductive layer 16 are successively laminated. These layers are formed by a method same as that for forming the first electroconductive layer 12 or the dielectric layer 13. It should be noted that, in the exemplary embodiment, it is preferable to form the second electroconductive layer 14 by a coating film-forming method. By employing the coating film-forming method, it is possible to fill the material constituting the second electroconductive layer 14 inside the contact holes 17 with ease.

With the above steps, the electroluminescent element 10 can be manufactured. It should be noted that, for stably using the electroluminescent element 10 for long periods and protecting the electroluminescent element 10 from outside, it is preferable to mount a protective layer or a protective cover (not shown). As the protective layer, polymer compounds, metal oxides, metal fluorides, metal borides, or silicon compounds such as silicon nitrides and silicon oxides can be used. Then, a lamination thereof can also be used. As the protective cover, glass plates, plastic plates with a surface treated with low hydraulic permeability, metals or the like can be used. It is preferable that such a protective cover is adopted with a method to be bonded to an element substrate by using a thermosetting resin or a photo-curable resin to be sealed. Moreover, at this time, predetermined spaces can be maintained by use of spacers, and it is preferred because scratches on the electroluminescent element 10 are prevented. Then, by filling the spaces with inert gases such as nitrogen, argon and helium, prevention of oxidation of the third electroconductive layer 16 provided on the outermost side is facilitated. Further, by putting desiccants such as barium oxide in the spaces, damage to the electroluminescent element 10 caused by moisture absorbed in the sequence of the aforementioned series of manufacturing processes is reduced.

The electroluminescent element 10 to which the exemplary embodiment is applied can be used in, for example, a display device, an illumination device and the like.

Though not particularly limited, as the display device, a so-called passive matrix display device is provided. The passive matrix display device usually includes: a display device substrate; plural anode wirings arranged on and in parallel with the display device substrate, which are composed of ITO (indium tin oxide) or the like; auxiliary anode wirings formed on end portions of respective anode wirings and electrically connected thereto; plural cathode wirings arranged to intersect respective anode wirings, which are composed of Al or Al alloy; auxiliary cathode wirings formed on end portions of respective cathode wirings and electrically connected thereto; an insulating film formed to cover the anode wirings; and plural cathode partitions formed on the insulating film along a direction perpendicular to the anode wirings to spatially separate the plural cathode wirings. In the insulating film, a rectangular-shaped opening portion is formed to expose part of the anode wirings, and the plural opening portions are arranged on the anode wirings in a matrix pattern.

In these opening portions, the electroluminescent elements 10 are provided between the anode wirings and the cathode wirings. Then, each opening portion serves as a pixel, and a display region is formed corresponding to the opening portions. The display device substrate is bonded to a sealing plate with a sealant, and accordingly, spaces where the electroluminescent elements 10 are provided are sealed.

The display device with such a configuration is able to supply a current to the electroluminescent elements 10 via the auxiliary anode wirings and the auxiliary cathode wirings by a driving device, to thereby cause the light-emitting layer to emit light, and accordingly, light is radiated. By controlling light emission and no light-emission of the electroluminescent elements corresponding to predetermined pixels with a controller, images can be displayed on the display device.

Moreover, usually, by a lighting circuit including a DC power supply and a control circuit inside thereof, an illumination device supplies a current between the first electroconductive layer 12 and the third electroconductive layer 16 of the electroluminescent element 10, to thereby cause the light-emitting layer 15 to emit light. The light emitted in the light-emitting layer 15 is taken to the outside through the substrate 11, and is utilized for illumination. The light-emitting layer 15 may be configured with light-emitting materials that emit white light, or, it may be possible to provide plural electroluminescent elements 10 using a light-emitting materials that output each of the green light (G), blue light (B) and red light (R), thus causing a synthetic light to have white color.

### EXAMPLES

Hereinafter, the present invention will be described in further detail based on Examples. However, the present invention is not limited to the following Examples.

### (Preparation of Electroluminescent Element and Evaluation of Properties)

In each of the following Examples 1 to 3 and Comparative Examples 1 and 2, a voltage was applied to a prepared electroluminescent element by a DC power supply (model SM2400 manufactured by Keithley Instruments Inc.) to be lighted up at an average brightness of 300 cd/m², and then light-emitting efficiency (cd/A) and a driving voltage (V) at that time were measured. The measurement results are shown in Table 1. It should be noted that, in Table 1, the refractive index of each layer constituting the electroluminescent element, the number of contact holes per a light-emitting region, and an occupancy ratio (occupancy) of the contact holes in the light-emitting region were described together.

### Example 1

With the following method, the electroluminescent element 10 was prepared.

First, on a glass substrate made of quartz glass (the substrate 11: 25 mm per side, a thickness of 1 mm), the first electroconductive layer 12 configured with an ITO film with a thickness of 150 nm and the dielectric layer 13 configured with a silicon dioxide (SiO₂) film with a thickness of 50 nm were formed by successive lamination by use of a sputtering device (E-401s manufactured by Canon ANELVA Corporation). Subsequently, on the dielectric layer 13, a photoresist (AZ1500 manufactured by AZ Electronic Materials) layer with a thickness of about 1 μm was formed by a spin coating method.

Subsequently, with a quartz (with a thickness of 3 mm) as a base material, a mask A corresponding to a pattern in which circles were arranged on hexagonal lattices was prepared, and the photoresist layer was exposed on a scale of 1/5 by use of a stepper exposure device (model NSR-1505i6 manufactured by Nikon Corporation). Next, the exposed photoresist layer was developed with 1.2% aqueous solution of tetramethyl ammonium hydroxide ((TMAH):(CH₃)₄NOH) for patterning the photoresist layer, and thereafter, heat at a temperature of 130° C. was applied for 10 minutes (post-baking process).

Next, by a reactive ion etching device (RIE-200iP manufactured by SAMCO Inc.), a dry etching process was applied on the photoresist layer by causing a reaction for 18 minutes with CHF₃ as a reactant gas under conditions of a pressure of 0.3 Pa and output bias/ICP=50/100 (W). Next, the residue of the resist was removed by a resist removing solution, and thereby the plural contact holes 17 passing through the dielectric layer 13 configured with the SiO₂ layer were formed. The contact hole 17 had a cylindrical shape with a diameter of 1 μm, and the contact holes 17 were arranged in a hexagonal lattice with a 4-μm pitch on an entire surface of the dielectric layer 13.

Subsequently, on the dielectric layer 13, an aqueous suspension (1.5% by mass in content) of a mixture of poly(3,4-ethylendioxythiophene) (PEDOT) and polystyrene sulfonate (PSS) (PEDOT:PSS=1:6 in mass ratio) was applied by the spin coating method (spin rate: 3000 rpm), and being left under a nitrogen atmosphere at the temperature of 140° C. for an hour to be dried, and accordingly, the second electroconductive layer 14 with a thickness of 20 nm was formed on the dielectric layer 13. The refractive index of the second electroconductive layer 14 was 1.5. It should be noted that the refractive index indicates a refractive index for the d line of sodium (589.3 nm) (the same shall apply hereafter).

Next, on the second electroconductive layer 14, a xylene solution of 1.1% by mass in content of a compound (A) indicated below was applied by the spin coating method (spin rate: 3000 rpm), and left under a nitrogen atmosphere at the temperature of 210° C. for an hour to be dried, and thereby a hole transport layer with a thickness of 20 nm was formed.

Subsequently, on the above-described hole transport layer, a xylene solution (a solid content concentration is 1.6% by mass) including a compound (B), a compound (C) and a compound (D) indicated below with mass ratio of 9:1:90 was applied by the spin coating method (spin rate: 3000 rpm), and left under a nitrogen atmosphere at the temperature of 140° C. for an hour to be dried, and thereby the light-emitting layer 15 with a thickness of 50 nm was formed. Either of refractive indices of the hole transport layer and the light-emitting layer 15 was 1.7.

Next, by a deposition method, on the above-described light-emitting layer 15, the cathode buffer layer composed of sodium fluoride (with a thickness of 4 nm) and the third electroconductive layer 16 composed of aluminum (with a thickness of 130 nm) were formed, to thereby prepare the electroluminescent element 10.

The prepared electroluminescent element 10 has a light-emitting surface on the substrate 11 side of the light-emitting layer 15 and includes one continuous light-emitting region. Moreover, when the electroluminescent element 10 was observed (viewed in a plan view) from the light-emitting surface side, the number of plural contact holes 17 in the above-described light-emitting region was about 2×10⁷. The ratio of the total area occupied by the plural contact holes 17 to the area of the light-emitting region was 0.057. It should be noted that the refractive index of the first electroconductive layer 12 composed of ITO was 1.8, and the refractive index of the dielectric layer 13 composed of SiO₂ was 1.4.

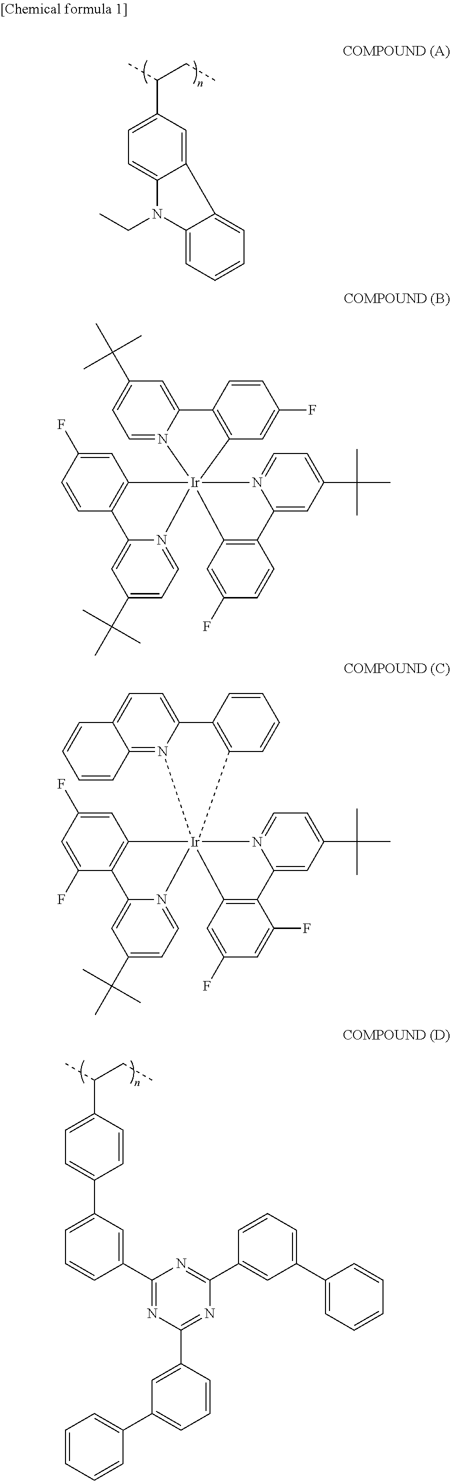

### Example 2

The composition of the light-emitting layer 15 was set such that the mass ratio of compounds indicated below was a compound (E):a compound (F):a compound (G):the compound (D)=10:0.4:0.6:89 (mass ratio), and other conditions were set as same as Example 1, to thereby prepare an electroluminescent element. The prepared electroluminescent element has a light-emitting surface on the substrate 11 side of the light-emitting layer 15 and includes one continuous light-emitting region. Moreover, when the electroluminescent element was observed (viewed in a plan view) from the light-emitting surface side, the number of plural contact holes 17 in the light-emitting region was about 2×10⁷. Moreover, to the area of the light-emitting region, the ratio of the total area occupied by the contact holes was 0.057. It should be noted that the refractive index of the light-emitting layer 15 was 1.7.

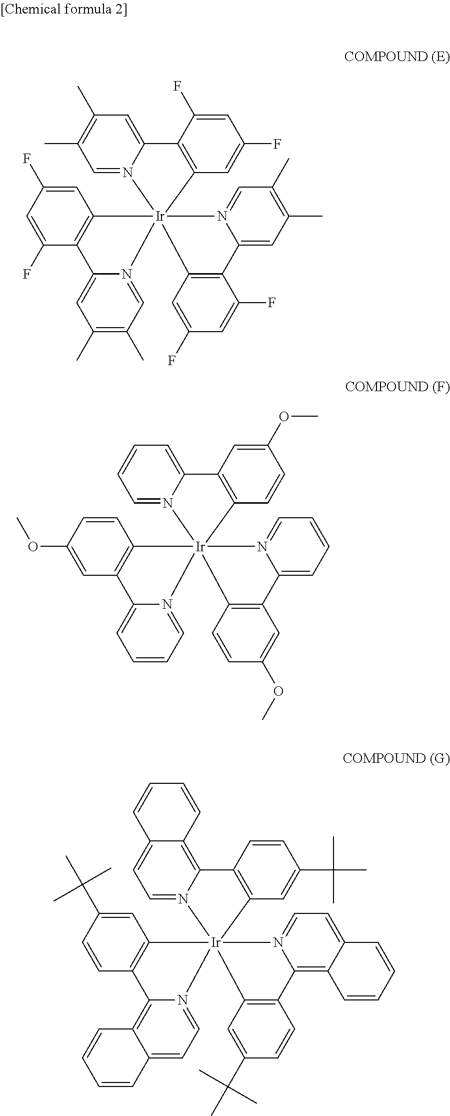

### Example 3

Under the conditions similar to those in Example 1, on a glass substrate (substrate 11) configured with quartz, an ITO film with a thickness of 150 nm was formed as the first electroconductive layer 12, and thereafter, a niobium pentoxide (Nb₂O₅) layer with a thickness of 50 nm (refractive index was 2.0) as the dielectric layer 13 was successively laminated and formed by use of a sputtering device.

Next, under the conditions similar to those in Example 1, a photoresist layer with a thickness of 1 μm was formed on the Nb₂O₅ layer, and thereafter, the photoresist layer was exposed on a scale of 1/5 by a stepper exposure device by use of a mask B made of quartz as a base material and corresponding to a pattern in which circles were arranged on hexagonal lattices. Thereafter, the photoresist layer was developed with 1.2% aqueous solution of TMAH and then heated at 130° C. for 10 minutes, and accordingly, the photoresist layer was patterned.

Subsequently, by a reactive ion etching device (RIE-200iP manufactured by SAMCO Inc.), a reaction was caused for 18 minutes with CHF₃ as a reactant gas under conditions of a pressure of 0.3 Pa and output bias/ICP=100/100 (W), to thereby perform a dry etching process on the photoresist layer. Thereafter, the reactant gas was changed to a mixed gas of Cl₃ and SiCl₄, and a reaction was caused for 5 minutes under conditions of a pressure of 1 Pa and output bias/ICP=200/100 (W), to further continue the dry etching process. Then, the residue of the resist was removed by the resist removing solution, to thereby form the contact holes 17 passing through the Nb₂O₅ layer (dielectric layer 13) and the ITO film (first electroconductive layer 12). The contact hole 17 had a cylindrical shape with a diameter of 0.5 μm, and the contact holes 17 were arranged in a hexagonal lattice with a 1.6-μm pitch on an entire surface of the Nb₂O₅ layer and the ITO film.

Next, by a sputtering device, on an entire surface on the Nb₂O₅ layer and inside the contact holes 17, an ITO film with a thickness of 20 nm as the second electroconductive layer 14 was formed. The refractive index of the second electroconductive layer 14 was 1.8.

Subsequently, under the conditions similar to those in Example 1, on the second electroconductive layer 14, the hole transport layer, the light-emitting layer 15, the cathode buffer layer and the third electroconductive layer 16 were successively laminated and formed, and thereby, the electroluminescent element was prepared.

The prepared electroluminescent element has a light-emitting surface on the substrate 11 side of the light-emitting layer 15 and includes one continuous light-emitting region. Moreover, when the electroluminescent element was observed (viewed in a plan view) from the light-emitting surface side, the number of contact holes 17 in the above-described light-emitting region was about 1.4×10⁸. Moreover, the ratio of the total area occupied by the plural contact holes 17 to the area of the light-emitting region was 0.089.

### Comparative Example 1

Except that a mask C was used as a pattern mask for exposing the photoresist layer, an electroluminescent element was prepared under the conditions similar to those in Example 1.

The prepared electroluminescent element had a light-emitting surface on the substrate 11 side of the light-emitting layer 15, and included one continuous light-emitting region. Further, the electroluminescent element had plural contact holes 17 having a cylindrical shape with a diameter of 2.5 μm and arranged in a hexagonal lattice with a 5-μm pitch on an entire surface of the SiO₂ layer. When the electroluminescent element was observed (viewed in a plan view) from the light-emitting surface side, the number of contact holes in the above-described light-emitting region was about 1.4×10⁷. The ratio of the total area occupied by the plural contact holes 17 to the area of the light-emitting region was 0.23.

### Comparative Example 2

Under the conditions same as those in Example 1, on a glass substrate made of quartz glass (the substrate 11), an ITO film with a thickness of 150 nm was formed as the first electroconductive layer 12, and thereafter, by use of a vacuum evaporator, a barium fluoride (BaF₂) layer (refractive index is 1.5) with a thickness of 50 nm was successively laminated and formed as the dielectric layer 13.

Next, under the conditions same as those in Example 1, the contact holes 17 were formed on an entire surface of the BaF₂ layer, and subsequently, under the conditions same as those in Example 1, the second electroconductive layer 14, the hole transport layer, the light-emitting layer 15, the cathode buffer layer and the third electroconductive layer 16 were successively laminated and formed.

TABLE 1

| | | Light- | | Refractive index of each layer | | | | | | |
|---|---|---|---|---|---|---|---|---|---|---|
| | | emitting | Driving | Second electro- | Light- | | Difference in | | Contact hole | |
| | | efficiency | voltage | conductive | emitting | Dielectric | refractive indices | | | Occupancy |
| | | (cd/A) | (V) | layer n1 | layer n2 | layer n3 | \|n1 − n3\| | \|n2 − n3\| | Number | rate |
| Example | 1 | 33 | 6.0 | 1.5 | 1.7 | 1.4 | 0.1 | 0.3 | 2 × 10⁷ | 0.057 |
| | 2 | 31 | 5.9 | 1.5 | 1.7 | 1.4 | 0.1 | 0.3 | 2 × 10⁷ | 0.057 |
| | 3 | 32 | 5.9 | 1.8 | 1.7 | 2.0 | 0.2 | 0.3 | 1.4 × 10⁸ | 0.089 |
| Comparative | 1 | 28 | 6.6 | 1.5 | 1.7 | 1.4 | 0.1 | 0.3 | 1.4 × 10⁷ | 0.23 |
| example | 2 | 25 | 6.0 | 1.5 | 1.7 | 1.5 | 0 | 0.2 | 2 × 10⁷ | 0.057 |

From the results shown in Table 1, in the electroluminescent element in which the plural contact holes 17 are formed in the dielectric layer 13 and the continuous light-emitting region is provided on the substrate 11 side of the light-emitting layer 15, it is learned that the electroluminescent elements in which the refractive indices of the second electroconductive layer 14 and the light-emitting layer 15 are not less than 1.5 and not more than 2.0, the absolute value of difference in the refractive index with the dielectric layer 13 is not less than 0.1, and the ratio of the total area occupied by the plural contact holes 17 that are formed not less than 10² per a light-emitting region to the area of the light-emitting region is not more than 0.1 (Examples 1 to 3) have the light-emitting efficiency (cd/A) of not less than 31 cd/A and the driving voltage (V) of not more than 6V. With any of these, white light having uniform brightness in the light-emitting surface was observed by visual inspection.

In contrast, in the electroluminescent element in which the ratio of the total area occupied by the plural contact holes 17 to the area of the light-emitting region is 0.23 (exceeding 0.1) (Comparative example 1), it is learned that the light-emitting efficiency (cd/A) remains at 28 cd/A, and the driving voltage (V) increases to 6.6V.

Further, in the electroluminescent element in which the absolute value of difference in the refractive indices between the second electroconductive layer 14 and the dielectric layer 13 is 0 (less than 0.1) (Comparative example 2), it is learned that, though the driving voltage (V) is not increased, the light-emitting efficiency (cd/A) remains at 25 cd/A.

### REFERENCE SIGNS LIST

10 . . . Electroluminescent element
11 . . . Substrate
12 . . . First electroconductive layer
13 . . . Dielectric layer
14 . . . Second electroconductive layer
15 . . . Light-emitting layer
16 . . . Third electroconductive layer
17 . . . Contact hole
17a . . . Minimum enclosing circle
110 . . . Lamination section

1. An electroluminescent element comprising:
a substrate; and
a lamination section including a first electroconductive layer, a dielectric layer, a second electroconductive layer, a light-emitting layer and a third electroconductive layer successively laminated on the substrate, wherein,
in the dielectric layer, a plurality of contact holes that pass through at least the dielectric layer are provided,
the first electroconductive layer and the second electroconductive layer are electrically connected inside the plurality of contact holes,
refractive indices of the second electroconductive layer and the light-emitting layer are not less than 1.5 and not more than 2.0, and an absolute value of a difference in each of the refractive indices with the refractive index of the dielectric layer is not less than 0.1, and
when viewed from a light-emitting surface side from which light emitted in the light-emitting layer is taken out,
(i) at least one continuous light-emitting region is provided, and
(ii) a number of the contact holes is not less than 10² per the one light-emitting region and a ratio of a total area occupied by the plurality of contact holes to an area of the light-emitting region is not more than 0.1.

2. The electroluminescent element according to claim 1, wherein the ratio of the total area occupied by the plurality of contact holes to the area of the light-emitting region is 0.001 to 0.1.

3. The electroluminescent element according to claim 1, wherein a cross-sectional shape of the contact hole in a case of being viewed in a plan view from the light-emitting surface side has a size able to be enclosed in a circle having a diameter in a range of 0.01 μm to 2 μm.

4. The electroluminescent element according to claim 1, wherein the contact hole are formed to further pass through the first electroconductive layer.

5. The electroluminescent element according to claim 1, wherein the first electroconductive layer, the dielectric layer and the second electroconductive layer are transparent to a wavelength of light emitted in the light-emitting layer.

6. The electroluminescent element according to claim 1, wherein both of the refractive indices of the second electroconductive layer and the light-emitting layer are larger than the refractive index of the dielectric layer.

7. The electroluminescent element according to claim 1, wherein both of the refractive indices of the second electroconductive layer and the light-emitting layer are smaller than the refractive index of the dielectric layer.

8. The electroluminescent element according to claim 1, wherein the second electroconductive layer includes one of conductive metal oxide and conductive polymer.

9. The electroluminescent element according to claim 1, wherein at least one layer, which is selected from a hole transporting layer, a hole blocking layer and an electron transporting layer, is further provided between the second electroconductive layer and the third electroconductive layer.

10. A method for manufacturing an electroluminescent element including a continuous light-emitting region, the method comprising:
a process of successively forming a first electroconductive layer and a dielectric layer on a substrate;
a process of providing a plurality of contact holes so that the plurality of contact holes pass through at least the dielectric layer, a number of the plurality of contact holes formed per the one light-emitting region is not less than 10², and a ratio of a total area occupied by the plurality of contact holes in the light-emitting region to an area of the light-emitting region is not more than 0.1;
a process of filling the contact holes with the second electroconductive layer so that the second electroconductive layer is electrically connected to the first electroconductive layer inside the plurality of contact holes, and forming the second electroconductive layer on the dielectric layer so that a refractive index of the second electroconductive layer is not less than 1.5 and not more than 2.0, and an absolute value of a difference in the refractive indices between the second electroconductive layer and the dielectric layer is not less than 0.1; and
a process of forming a light-emitting layer on the second electroconductive layer so that a refractive index of the light-emitting layer is not less than 1.5 and not more than 2.0, and an absolute value of a difference in the refractive indices between the light-emitting layer and the dielectric layer is not less than 0.1, and further forming a third electroconductive layer successively.

11. The method for manufacturing an electroluminescent element according to claim 10, wherein the second electroconductive layer is formed by a coating film-forming method.

12. A display device comprising the electroluminescent element according to claim 1.

13. An illumination device comprising the electroluminescent element according to claim 1.
